(19) United States
(12) Patent Application Publication
(10) Pub. No.: US 2026/0286560 A1
(43) Pub. Date: Sep. 24, 2026

(54) ELECTRODEPOSITED COPPER FOIL AND APPLICATIONS THEREOF

(71) Applicant: DUPONT ELECTRONICS, INC., Wilmington, DE (US)

(72) Inventors: YA-MEI LIN, HSINCHU CITY (TW); SHIH-CHING LIN, HSINCHU CITY (TW); CHI YEN, HSINCHU CITY (TW)

(21) Appl. No.: 19/560,366

(22) Filed: Mar. 9, 2026

Related U.S. Application Data
(60) Provisional application No. 63/773,840, filed on Mar. 18, 2025.

(51) Int. Cl. C25D 3/38; C25D 1/04

(52) U.S. Cl. CPC C25D 3/38; C25D 1/04

(57) ABSTRACT

The present disclosure provides an electrodeposited copper foil having a smooth matte side. The said matte side has a maximum height of profile Rz of 150 nm or less; an arithmetic mean height Sa of 100 nm or less; a root mean square height Sq of 100 nm or less; and a developed interfacial area ratio Sdr of 2% or higher; wherein the Rz, Sa, Sq and Sdr are measured according to ISO 4287-1997 using an atomic force microscope. The present disclosure also provides a method for manufacturing an electrodeposited copper foil and an article comprising an electrodeposited copper foil.

### FIELD OF THE INVENTION

The present disclosure provides an electrodeposited copper foil having a smooth matte side and applications of the electrodeposited copper foil. The electrodeposited copper foil has low surface roughness and may provide enhanced interfacial bonding strength with other materials.

### BACKGROUND

Generally, copper foils can be classified into two major categories according to the manufacturing methods thereof, i.e., rolled and annealed copper foils (RA copper foils) and electrodeposited copper foils (ED copper foils).

The manufacturing methods of RA copper foils typically involve providing a comparably thicker copper sheet (generally over 200 μm), subjecting it to multiple rolling and annealing processes to eventually form a copper foil with a thickness of 70 μm or less, with some thicknesses commonly seen in the art being 9 μm, 12 μm, 18 μm, 35 μm, and 70 μm. Due to the repetitive pressing by rollers on both sides of the copper sheet, one characteristic of RA copper foils is that both sides exhibit a relatively smooth and low roughness surface.

On the other hand, ED copper foils are generally produced through electrolysis or electroplating. The production methods of electrodeposited copper foil typically involve applying a direct current in a copper sulfate electrolyte solution, and reducing copper ions to form a copper foil deposited on the surface of the cathode. The thickness of the deposited copper foil gradually increases during electrolysis or electroplating, eventually reaching the targeted thickness. Unlike RA copper foil, a side of ED copper foil would appear shiny (referred to as the “shiny side” or “S side”) while the other would appear matte (referred to as the “matte side” or “M side”), wherein the “shiny side” is the side that was in contact with the surface of the cathode and the “matte side” is the side that was in contact with the electroplating solution.

The aforementioned copper foils, including RA copper foils and ED copper foils, can be applied in various fields such as printed circuit boards and anode current collectors for lithium batteries. In the case where a copper foil is used in a printed circuit board as a conductor for signal transmission, the signal transmission loss would be less if the copper foil has a lower surface roughness. In the case where a copper foil is used in an anode current collector for a lithium battery, if the surface roughness of the copper foil is too high, the copper foil may react with the anode, resulting in interlayer interface fracture. Both cases above show that it may be preferable for the surface roughness of the copper foil to be as low as possible. In recent years, in the pursuit of higher performance such as higher frequency, higher speed signal transmission or higher energy storage in the industry, the demand on printed circuit boards and lithium batteries have grown, and the requirements for the surface roughness of the copper foil have also become stricter accordingly. Furthermore, since copper foils are often attached to dielectric materials or anode materials (such as carbon powder, silicon-based materials, or mixtures of carbon powder and silicon-based materials) in printed circuit boards or lithium batteries, the bonding strength between the copper foils and these materials is also an important consideration factor. If the bonding strength is too low, the resulting printed circuit boards or anode current collectors for lithium batteries will not only have limitation on their usage but also suffer negative impacts on their lifespan.

Although RA copper foils have the advantage of having smooth and flat surfaces on both sides, they are generally more expensive than ED copper foils. Additionally, due to low surface roughness, the bonding strength of RA copper foils to other materials is relatively poor. To address the problem of poor bonding strength of RA copper foils, one common means utilized in the industry is to perform roughening on one side of the copper foil. This may involve electroplating to form “bump” particles (i.e., copper nodules) on the surface of the copper foil to increase the surface area of the copper foil, and thereby enhancing the bonding strength between the roughened surface and dielectric materials or anode materials. In this regard, effort has been dedicated in the industry primarily in developing finer and more uniform copper nodules to minimize their impact on increasing the surface roughness.

On the other hand, ED copper foils have cost advantage over RA copper foils while surface roughness on the matte side is often too high for applications in high-performance printed circuit boards and lithium batteries. Common ways to improve ED copper foils performance is adjusting processing parameters in electrodeposition processes or adjusting components in electrolyte formulations. The copper foils obtained therefrom may be referred to as very low profile (VLP) copper foils. However, similar to RA copper foils, roughening is often needed to be performed on one side of the VLP ED copper foils to enhance the interface bonding strength with other materials. Moreover, if one intends to reduce the current density during electrodeposition process in the hope of reducing the roughness of the matte side of the ED copper foil, this often leads to lower production efficiency. Meanwhile, if one intends to take the approach of adjusting electrolyte formulations to improve roughness, a large number of additives such as leveling agents or similar additives are often used. Consequently, a considerable amount of activated carbon may be needed to absorb the degraded additives to allow repeat use of the electrolyte, which will incur cost for handling used/waste activated carbon.

From the viewpoint of conventional technologies described above, “low surface roughness” and “high bonding surface area” appear to be mutually exclusive characteristics, or at least hard to co-exist, for copper foils. Therefore, developing an electrodeposited copper foil that possesses both low surface roughness and high bonding surface area would bring great benefit to the industry.

### SUMMARY

In view of the aforementioned technical problems, the present disclosure provides an electrodeposited copper foil which, even without roughening, simultaneously possesses a low surface roughness and a high bonding surface area (provided by a plurality of nanoscale pores). The electrodeposited copper foil of the present disclosure is particularly suitable for used in printed circuit boards designed for higher frequency and higher speed uses as well as anode current collectors for lithium batteries. The present disclosure also provides a method for manufacturing the aforementioned electrodeposited copper foil, which may be performed at higher current density.

Accordingly, an objective of the present disclosure is to provide an electrodeposited copper foil, which has a matte side having:
a maximum height of profile Rz of 150 nm or less;
an arithmetic mean height Sa of 100 nm or less;
a root mean square height Sq of 100 nm or less; and
a developed interfacial area ratio Sdr of 2% or higher;
wherein the Rz, Sa, Sq and Sdr are measured according to ISO 4287-1997 using an atomic force microscope.

In an embodiment of the present disclosure, the electrodeposited copper foil has a thickness ranging from 3 μm to 70 μm.

In an embodiment of the present disclosure, the electrodeposited copper foil has been subjected to at least one surface treatment on at least one side.

In an embodiment of the present disclosure, the at least one surface treatment comprises pickling, thermal resistance treatment, anti-oxidation treatment, silane treatment, or a combination thereof.

In an embodiment of the present disclosure, the at least one surface treatment does not comprise roughening.

Another objective of the present disclosure is to provide a method for manufacturing the aforementioned electrodeposited copper foil, which comprises:
i) providing an electrolyte solution at a temperature of 35° C. to 70° C. in an electrolytic cell equipped with an anode plate and a cathode drum;
ii) applying an electric current at a current density of 20 A/dm² to 100 A/dm² to the anode plate and the cathode drum in rotating state;
iii) providing a copper foil on the cathode drum in rotating state by electrodeposition; and
iv) separating the copper foil obtained from step iii);
wherein the electrolyte solution comprises:
   120 g/L to 450 g/L of copper sulfate;
   30 g/L to 140 g/L of sulfuric acid;
   5 ppm to 60 ppm of chloride ion;
   1 ppm to 39 ppm of bis-(sodium sulfopropyl)-disulfide; and
   1 ppm to 39 ppm of a nitrogen-containing cationic polymer.

In an embodiment of the present disclosure, a total amount of chloride ion, bis-(sodium sulfopropyl)-disulfide and the nitrogen-containing cationic polymer is 100 ppm or less.

In an embodiment of the present disclosure, the nitrogen-containing cationic polymer is a reaction product of a diamine of Formula (I) and a diepoxide of Formula (II) in 1:1 molar ratio:

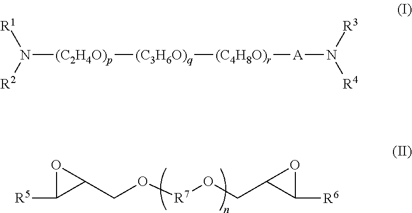

wherein
R¹, R², R³ and R⁴ are independently H or C₁-C₃ alkyl;
R¹ and R⁶ are independently H or C₁-C₄ alkyl;
R⁷ is a divalent linking group selected from the group consisting of C₂-C₈ alkylene, C₅-C₁₀ cycloalkylene, and C₁-C₄ alkylene-C₅-C₁₀ cycloalkylene-C₁-C₄ alkylene, and R⁷ is optionally substituted with C₁-C₄ alkyl or —OH;
A is a divalent linking group selected from the group consisting of C₂-C₈ alkylene, C₅-C₁₀ cycloalkylene, C₁-C₄ alkylene-C₅-C₁₀ cycloalkylene-C₁-C₄ alkylene, C₆-C₂₀ arylene, and C₁-C₄ alkylene-C₆-C₂₀ arylene-C₁-C₄ alkylene, and A is optionally substituted with C₁-C₄ alkyl or —OH;
p, q and r are independently an integer of 0 to 10, with the proviso that p, q and r are not simultaneously 0;
n is an integer of 1 to 10; and
the nitrogen-containing cationic polymer has a weight average molecular weight of 1,000 or less.

Another objective of the present disclosure is to provide an article which comprises the aforementioned electrodeposited copper foil.

In an embodiment of the present disclosure, the article is an anode electrode collector, a resin-coated copper, a copper clad laminate, a flexible copper clad laminate, a rigid printed circuit board, a flexible printed circuit board, or a rigid-flexible printed circuit board.

To render the above objectives, technical features, and advantages of the present disclosure more apparent, the present disclosure will be described in detail with reference to some embodiments hereinafter.

### BRIEF DESCRIPTION OF THE DRAWINGS

FIG. 1 shows a schematic cross-sectional view of an embodiment of an electrodeposited copper foil of the present disclosure, which has a matte side that has low surface roughness and a plurality of nanoscale pores.

FIG. 2 shows SEM images of the surface morphology of the matte side respectively for the copper foils of the Examples and Comparative examples, with (A) representing Example E1, (B) representing Comparative Example CE11, and (C) representing Comparative Example CE12.

FIG. 3 shows SEM images of the cross-sectional morphology respectively for the copper foils of the Examples and Comparative examples, with (A) representing Example E1, (B) representing Comparative Example CE11, and (C) representing Comparative Example CE12.

FIG. 4 shows AFM images of the matte side respectively for the copper foils of the Examples and Comparative examples, with (A) representing Example E1, (B) representing Comparative Example CE111, and (C) representing Comparative Example CE12.

### DETAILED DESCRIPTION

Hereinafter, some embodiments of the present disclosure will be described in detail. However, the present disclosure may be embodied in various embodiments, and the protection scope of the present disclosure should not be limited to those described in the specification.

As used herein, the expressions “a”, “the”, or the like recited in the specification and in the claims should include both the singular and the plural forms unless stated otherwise.

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this application belongs. In case of conflict, the present specification, including definitions, will prevail.

Unless stated otherwise, all percentages, parts, ratios, etc., are by weight.

As used herein, the term “composed of” has the same meaning with “comprising.” As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps, features, components, or elements do not materially affect the basic and novel characteristic(s) of the claimed application. The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

The electrodeposited copper foil of the present disclosure and applications thereof are described in detail below.

### Electrodeposited Copper Foil

The present disclosure provides an electrodeposited copper foil that has a matte side having low surface roughness and a high bonding surface area which is believed to be provided by a plurality of nanoscale pores.

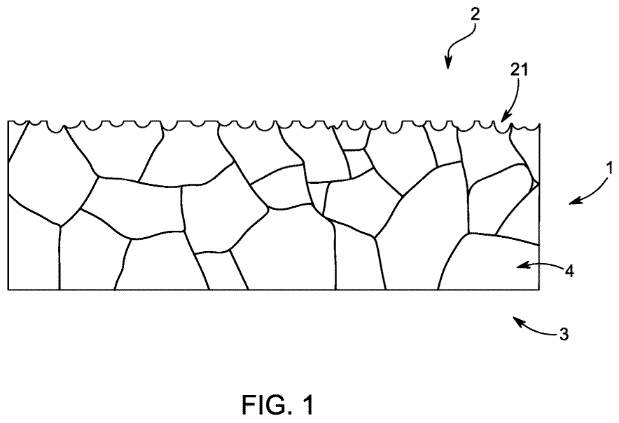

FIG. 1 shows a schematic cross-sectional view of an embodiment of an electrodeposited copper foil of the present disclosure. The electrodeposited copper foil 1 comprises a matte side 2 and a shiny side 3 and is composed of multiple crystal grains 4 which may have the same or different orientations. The matte side 2 of the electrodeposited copper foil 1 has a plurality of nanoscale pores 21 and low surface roughness.

In the present disclosure, the surface roughness can be expressed by maximum height of profile (Rz), arithmetic mean height (Sa), and root mean square height (Sq). In addition, information regarding surface area can be expressed by developed interfacial area ratio (Sdr). The Rz, Sa, Sq and Sdr can be measured according to ISO 4287-1997 using an atomic force microscope.

The maximum height of profile (Rz) of the matte side of the electrodeposited copper foil can be 150 nm or less, or 140 nm or less, or 30 nm to 140 nm. For example, the Rz of the matte side of the electrodeposited copper foil can be 30 nm, 35 nm, 40 no, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 no, 130 nm, 135 nm, 140 nm, 145 nm, or 150 nm, or within a range between any two of the values described herein.

The arithmetic mean height (Sa) of the matte side of the electrodeposited copper foil can be 100 nm or less, or 90 nm or less, or 20 nm to 90 nm. For example, the Sa of the matte side of the electrodeposited copper foil can be 20 nm, 25 nm, 30 nm, 35 nm, 40 nm, 45 nm, 50 nm, 55 nm, 60 nm, 65 nm, 70 no, 75 nm, 80 nm, 85 nm, 90 nm, 95 no, or 100 nm, or within a range between any two of the values described herein.

The root mean square height (Sq) of the matte side of the electrodeposited copper foil can be 100 nm or less, or 30 nm to 100 nm. For example, the Sq of the matte side of the electrodeposited copper foil can be 30 nm, 35 nm, 40 nm, 45 nm, 50 nm, 55 nm, 60 nm, 65 nm, 70 nm, 75 nm, 80 nm, 85 nm, 90 nm, 95 rim, or 100 nm, or within a range between any two of the values described herein.

When the Rz, Sa and Sq of the matte side of the electrodeposited copper foil are within the ranges above, the matte side may be considered as having low surface roughness. A low surface roughness may reduce friction or tendency to react with other materials, so that signal transmission loss or interface fracture may be reduced when the electrodeposited copper foil is applied to a printed circuit board or a lithium battery.

The developed interfacial area ratio (Sdr) of the matte side of the electrodeposited copper foil can be 2% or higher, or 2% to 20%, or 2% to 12%, or 2% to 10%. For example, the Sdr of the matte side of the electrodeposited copper foil can be 2%, 2.1% 2.2%, 2.5%, 3%, 3.5%, 4%, 4.5%, 5%, 5.5%, 6%, 6.5%, 7%, 7.5%, 8%, 8.5%, 9%, 9.5%, 10%, 11%, 12%, 13%, 14%, 15%, 16%, 17%, 18%, 19%, or 20%, or within a range between any two of the values described herein.

In the present disclosure, a “nanoscale pore” may refer to a concave structure on the surface of matte side of the electrodeposited copper foil which has a dimension of no more than 500 nm in width and no more than 500 nm in depth. The nanoscale pore can be observed under a scanning electron microscope (SEM) in top view and cross-sectional view, and its dimension can be measured and calculated with the aid of a software.

It is believed that the plurality of nanoscale pores on the surface of the matte side provide a high bonding surface area for the electrodeposited copper foil. Thus, even without roughening, the electrodeposited copper foil of the present disclosure may have an enhanced interfacial bonding strength with other materials, such as dielectric materials of printed circuit boards or anode materials of lithium batteries.

The interfacial bonding strength can be evaluated by laminating the electrodeposited copper foil with a substrate, and then measuring the force required to peel the electrodeposited copper foil off from the substrate, i.e., peeling strength. In an embodiment of the present disclosure, the substrate is an epoxy resin and the peeling strength may range from 0.10 to 0.60 kN/m, or 0.20 to 0.50 kN/m.

The thickness of the electrodeposited copper foil can be adjusted based on the desired application. In an embodiment of the present disclosure, the electrodeposited copper foil has a thickness ranging from 3 μm to 70 μm, such as 3 μm, 9 μm, 12 μm, 18 μm, 35 μm, or 70 μm, but the present disclosure is not limited thereto.

The electrodeposited copper foil of the present disclosure can be produced such as by the method discussed in the following section.

### Method for Manufacturing Electrodeposited Copper Foil

The present disclosure also provides a method for manufacturing the aforementioned electrodeposited copper foil. The method comprises: i) providing an electrolyte solution at a temperature of 35° C. to 70° C. in an electrolytic cell equipped with an anode plate and a cathode drum; ii) applying an electric current at a current density of 20 A/dm² to 100 A/dm² to the anode plate and the cathode drum in rotating state; iii) providing a copper foil on the cathode drum in rotating state by electrodeposition; and iv) separating the copper foil obtained from step iii). It is noteworthy that the manufacturing method may be performed at a high current density ranging from 20 A/dm² to 100 A/dm², or 40 A/dm² to 100 A/dm², which may be considered efficient for mass production.

In the present disclosure, the electrolyte solution used in the method comprises: 120 g/L to 450 g/L, or 200 g/L to 300 g/L, of copper sulfate; 30 g/L to 140 g/L, or 40 g/L to 120 g/L, of sulfuric acid; 5 ppm to 60 ppm, or 10 ppm to 50 ppm, of chloride ion; 1 ppm to 39 ppm, or 1 ppm to 10 ppm, of bis-(sodium sulfopropyl)-disulfide; and 1 ppm to 39 ppm, or 1 ppm to 10 ppm, of a nitrogen-containing cationic polymer. The total amount of chloride ion, bis-(sodium sulfopropyl)-disulfide and the nitrogen-containing cationic polymer may be 100 ppm or less, such as 7 ppm to 100 ppm.

In an embodiment of the present disclosure, the nitrogen-containing cationic polymer is a reaction product of a diamine of Formula (I) and a diepoxide of Formula (II) in 1:1 molar ratio:

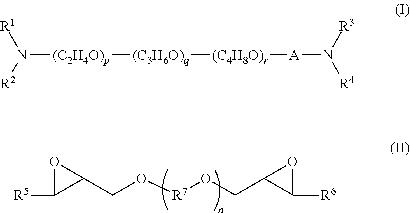

wherein
R¹, R², R³ and R⁴ are independently H or C₁-C₃ alkyl;
R⁵ and R⁶ are independently H or C₁-C₄ alkyl;
R⁷ is a divalent linking group selected from the group consisting of C₂-C₈ alkylene, C₅-C₁₀ cycloalkylene, and C₁-C₄ alkylene-C₅-C₁₀ cycloalkylene-C₁-C₄ alkylene, and R⁷ is optionally substituted with C₁-C₄ alkyl or —OH;
A is a divalent linking group selected from the group consisting of C₂-C₈ alkylene, C₅-C₁₀ cycloalkylene, C₁-C₄ alkylene-C₅-C₁₀ cycloalkylene-C₁-C₄ alkylene, C₆-C₂₀ arylene, and C₁-C₄ alkylene-C₆-C₂₀ arylene-C₁-C₄ alkylene, and A is optionally substituted with C₁-C₄ alkyl or —OH;
p, q and r are independently an integer of 0 to 10, with the proviso that p, q and r are not simultaneously 0;
n is an integer of 1 to 10; and
the nitrogen-containing cationic polymer has a weight average molecular weight of 1,000 or less.

The manufacturing method of the electrodeposited copper foil of the present disclosure may or may not involve a surface treatment. In an embodiment of the present disclosure, the electrodeposited copper foil has been subjected to at least one surface treatment on at least one side, and examples of the at least one surface treatment include but are not limited to pickling, thermal resistance treatment, anti-oxidation treatment, silane treatment, and combinations thereof. For example, if the electrodeposited copper foil is to be used in a high-speed high frequency (HSHF) printed circuit board, desired surface treatment may be pickling, thermal resistance treatment, anti-oxidation treatment and/or silane treatment; and if the electrodeposited copper foil is to be used in a lithium battery, desired surface treatment may be anti-oxidation treatment by soaking the electrodeposited copper foil in chromic acid.

As the electrodeposited copper foil of the present disclosure may have excellent bonding strength even without roughening, in an embodiment of the present disclosure, the at least one surface treatment does not comprise roughening.

Before being used or subjected to testing, the electrodeposited copper foil may be treated in a copper protecting agent to prevent it from tarnishing or oxidizing. The treatment may be performed by immersing the electrodeposited copper foil into the copper protecting agent for 3-10 seconds, such as 5 seconds. Commercially available copper protecting agent can be such as CUPROTEC™ available from DuPont.

Exemplary manufacturing methods of the electrodeposited copper foil are provided in the Example section below.

### Applications of Electrodeposited Copper Foil

The electrodeposited copper foil of the present disclosure has the advantage of simultaneously possessing a low surface roughness and a high bonding surface area and may be desirable in various fields. Therefore, the present disclosure also provides an article which comprises the aforementioned electrodeposited copper foil. The article can be, for example, an anode electrode collector, a resin-coated copper, a copper clad laminate, a flexible copper clad laminate, a rigid printed circuit board, a flexible printed circuit board, or a rigid-flexible printed circuit board, but the present disclosure is not limited thereto.

### EXAMPLES

Hereinafter, some examples are provided to illustrate the present disclosure. These examples are provided for illustrative purpose only and are not intended to limit the scope of the present disclosure.

The raw materials used in the Examples and Comparative Examples were listed in Table 1 below.

TABLE 1

| | Model name and | |
|---|---|---|
| Raw material | manufacturer | Description |
| SPS | Available from HOPAX | Bis-(sodium sulfo- |
| | | propyl)-disulfide |
| NCP-1 | Copper Gleam ™ T6, | Nitrogen-containing |
| | available from Dupont | cationic polymer, |
| | | Mw = 500~1000 |
| Copper sulfate | Available from Sigma- | — |
| | Aldrich | |
| Sulphuric acid | Available from Sigma- | — |
| | Aldrich | |
| Hydrochloric | Available from Sigma- | Source for chloride ion |
| acid | Aldrich | |
| Copper | CUPROTEC ™, available | — |
| protecting agent | from DuPont | |
| Substrate | NPG170D, available from | A prepreg formed |
| | Nan Ya Plastics Corporation | from epoxy resin |

### Preparation of Electrodeposited Copper Foil

### Examples E1-E8 and Comparative Examples CE1-CE10

The electrodeposited copper foils of Examples E1-E8 and CE1-CE10 were prepared as follows.

According to the proportions listed in Table 2, chloride ions (provided by hydrochloric acid), a nitrogen-containing cationic polymer (NPC-1) and bis-(sodium sulfopropyl)-disulfide (SPS) were mixed with 260 g/L of copper sulfate and 80 g/L of sulfuric acid to form a base electrolyte solution.

A rotary electrode instrument was used for the electroplating process. The rotary electrode instrument had a titanium drum as the cathode (i.e., the negative electrode) and a dimensional stable anode (DSA) plate (i.e., the positive electrode), and was equipped with a direct current (DC) power supply. The base electrolyte solution formed above was filled into the space between the anode and cathode. The electroplating process was performed with a current density of 60 A/dm², a temperature of electrolyte solution according to Table 2, a cathode rotation speed of 400 rpm, and a duration of electroplating according to Table 2 to directly form an electrodeposited copper foil with a corresponding thickness as shown in Table 2.

After electroplating is completed, the electrodeposited copper foil was taken from the titanium wheel for surface treatment. Specifically, the electrodeposited copper foil was immersed in a copper protective agent (CUPROTEC™, available from DuPont) for 5 seconds, and then taken out and dried with compressed air.

### Comparative Example CE11

The electrodeposited copper foil of Comparative Example CE11 is a commercialized product of NC-WS, available from Furukawa Circuit Foil Taiwan Corporation, having a nominal thickness of 12 μm.

### Comparative Example CE12

The electrodeposited copper foil of Comparative Example CE12 is a commercialized product of JXEFL-BHM, available from JX Nippon Mining & Metals Corporation, having a nominal thickness of 12 μm.

TABLE 2

| | | | | Temper- | | Thick- |
|---|---|---|---|---|---|---|
| | | | | ature of | Duration | ness of |
| | Chloride | | | electrolyte | of electro- | copper |
| | ion | NCP-1 | SPS | solution | plating | foil |
| | (ppm) | (ppm) | (ppm) | (° C.) | (Sec) | (μm) |
| E1 | 15 | 5 | 5 | 40 | 45 | 12 |
| E2 | 15 | 5 | 5 | 40 | 188 | 50 |
| E3 | 15 | 5 | 1 | 60 | 45 | 12 |
| E4 | 15 | 1 | 5 | 60 | 45 | 12 |
| E5 | 15 | 1 | 5 | 60 | 188 | 50 |
| E6 | 40 | 5 | 5 | 60 | 45 | 12 |
| E7 | 40 | 1 | 5 | 40 | 45 | 12 |
| E8 | 40 | 5 | 5 | 60 | 188 | 50 |
| CE1 | 15 | 0 | 5 | 40 | 45 | 12 |
| CE2 | 15 | 0 | 5 | 40 | 188 | 50 |
| CE3 | 15 | 5 | 0 | 40 | 45 | 12 |
| CE4 | 15 | 5 | 0 | 40 | 188 | 50 |
| CE5 | 40 | 0 | 5 | 60 | 45 | 12 |
| CE6 | 40 | 0 | 5 | 60 | 188 | 50 |
| CE7 | 15 | 0 | 0 | 40 | 45 | 12 |
| CE8 | 15 | 0 | 0 | 40 | 188 | 50 |
| CE9 | 0 | 0 | 0 | 40 | 45 | 12 |
| CE10 | 0 | 0 | 0 | 40 | 188 | 50 |
| CE11 | NA | NA | NA | NA | NA | 12 |
| CE12 | NA | NA | NA | NA | NA | 12 |

*NA = Not applicable

### Evaluation of Electrodeposited Copper Foil

The electrodeposited copper foils of Examples E1-E8 and CE1-CE10 were tested according to the following methods and the results are shown in Table 3.

### [AFM Analysis—Rz, Sa, Sq and Sdr]

The roughness of the electrodeposited copper foil is measured using an atomic force microscope (AFM) (Anasys nanoIR3, available from Bruker). The specimen is prepared by cutting the electrodeposited copper foil to a suitable size and adhering it to a magnet with a diameter of 15 mm using a copper tape, wherein the matte side of the electrodeposited copper foil is faced away from the magnet for observation under AFM. The test is performed with a scanning frequency of 0.3 Hz, a scan area of 15 μm×15 μm, and a resolution of 200 points in both the x and y directions.

Afterward, the AFM image of the electrodeposited copper foil is analyzed using the Gwyddion software to obtain information regarding the surface characteristics of the specimen. The color scale of the scale bar is adjusted to change the viewing of data such as Sa or Sq obtained from the surface measurements.

Rz (maximum height of profile) represents the absolute difference between the highest peaks and the lowest valleys in the surface profile within a given sampling length. The test is carried out for five different sampling lengths, and the five obtained values are averaged.

Sa (arithmetic mean height) represents an average of absolute deviations of all points from a reference surface. It is obtained by taking a arithmetic mean surface as the reference surface, measuring the absolute difference in height from each point to the mean surface, and averaging the values measured at all points.

Sq (root mean square height) also compares the absolute differences in height measured at all points with a reference surface. However, by squaring the measured values before averaging, and then taking the square root of that average, the contributions of higher peaks and deeper valleys are emphasized.

Sdr (developed interfacial area ratio) represents the increase in surface area due to roughness compared to a smooth, flat surface. It may be calculated as the percentage of the surface area contributed by the surface texture relative to a reference planar surface area. Specifically, Sdr is calculated as the percentage increase of the actual surface area relative to the projected surface area according to the following equation:

$$Sdr = ( actual surface area / projected surface area ) - 1$$

Accordingly, a completely flat surface has a Sdr value of 0. When Sdr=0.7, it means that the actual surface area is 70% greater than the projected surface area or, equivalently, that the actual surface area is 1.7 times the projected surface area.

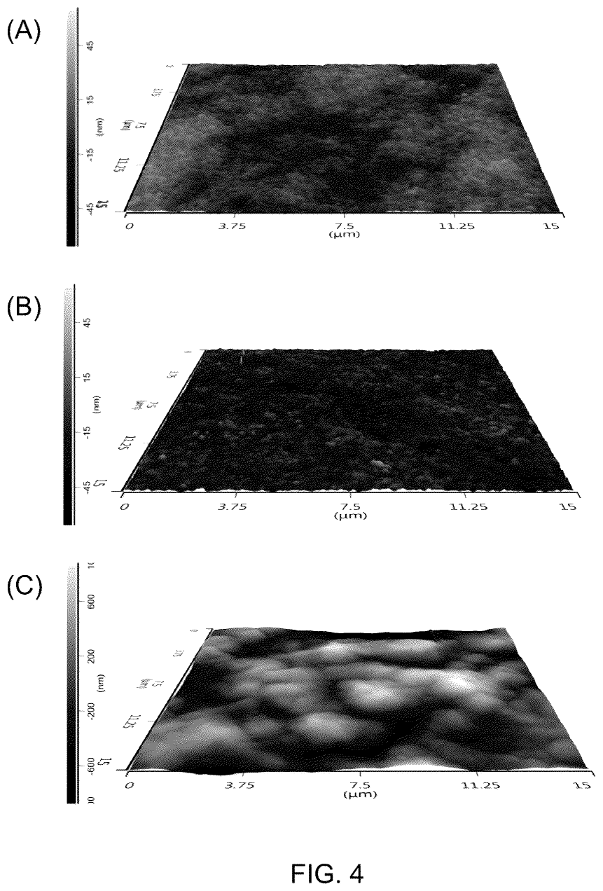

The test results for Rz, Sa, Sq and Sdr are recorded in Table 3. In addition, the AFM images of the matte side of the electrodeposited copper foil are shown in FIG. 4 for Example E1 in (A), Comparative Example CE11 in (B), and Comparative Example CE12 in (C).

### [SEM Analysis—Morphology]

The electrodeposited copper foil is cut into a size of 0.5 cm×0.5 cm as a specimen and attached to a holder. The specimen is placed along with the holder into a scanning electron microscope (SEM) (JEOL-IT300HR, available from JOEL) for observation. For each specimen, SEM images are taken at an accelerating voltage of 10 kV with the holder tilted at an angle of 45°. The SEM images may be taken at different magnifications if appropriate.

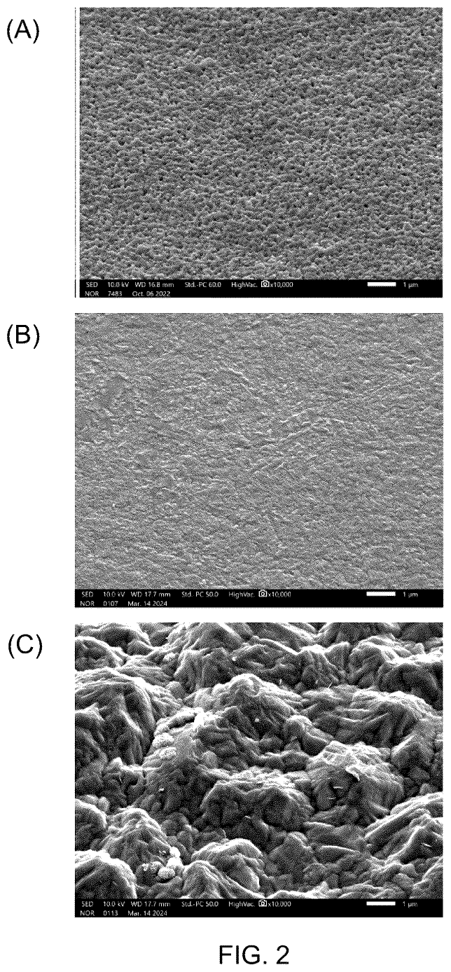

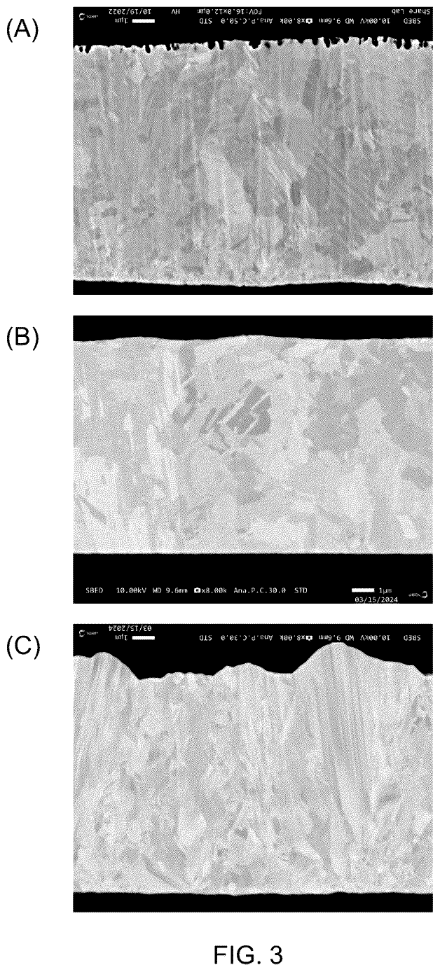

The morphology of the electrodeposited copper foil is then analyzed based on the SEM images. Representatively, FIG. 2 and FIG. 3 show the surface morphology and cross-sectional morphology, respectively, for Example E1 in (A), Comparative Example CE11 in (B), and Comparative Example CE12 in (C). If nanoscale pores can be found on the surface of the electrodeposited copper foil (such as in the SEM images of FIGS. 2-3 in (A)), the result is recorded as “∘”; whereas if no nanoscale pores can be found on the surface of the electrodeposited copper foil (such as in the SEM images of FIGS. 2-3 in (B) and (C)), the result is recorded as “x”. The analysis results are summarized in Table 3.

### [Peeling Strength]

The electrodeposited copper foil is laminated with a substrate (NPG170D, available from Nan Ya Plastics Corporation) by hot-press to form a specimen, with the matte side of the electrodeposited copper foil facing the substrate. The specimen is then subjected to surface etching to form a strip-like circuit with a line width of 1 mm. After that, the etched specimen is tested according to IPC TM650 2.4.8 using a universal material tensile tester (EZ-S50N, available from Shimadzu), and the peeling strength is recorded in kN/m in Table 3. A higher peeling strength means that the electrodeposited copper foil has a higher interfacial bonding strength with the substrate.

TABLE 3

| | | | | | | Peeling |
|---|---|---|---|---|---|---|
| | Rz | Sa | Sq | Sdr | Nanoscale | strength |
| | (nm) | (nm) | (nm) | (%) | pores | (kN/m) |
| E1 | 48 | 34 | 43 | 2.67 | ∘ | 0.31 |
| E2 | 36 | 27 | 35 | 3.56 | ∘ | 0.22 |
| E3 | 88 | 63 | 81 | 4.44 | ∘ | 0.43 |
| E4 | 120 | 83 | 97 | 4.89 | ∘ | 0.23 |
| E5 | 95 | 67 | 84 | 8.44 | ∘ | 0.21 |
| E6 | 85 | 58 | 72 | 2.67 | ∘ | 0.25 |
| E7 | 137 | 82 | 93 | 2.22 | ∘ | 0.24 |
| E8 | 123 | 84 | 95 | 4.44 | ∘ | 0.31 |
| CE1 | 643 | 351 | 468 | 18.67 | x | 0.17 |
| CE2 | 875 | 496 | 594 | 32.89 | x | 0.34 |
| CE3 | 578 | 345 | 438 | 13.78 | x | 0.12 |
| CE4 | 864 | 378 | 602 | 40.00 | x | 0.27 |
| CE5 | 731 | 384 | 492 | 28.00 | x | 0.15 |
| CE6 | 812 | 431 | 694 | 76.89 | x | 0.38 |
| CE7 | 853 | 465 | 718 | 81.33 | x | 0.21 |
| CE8 | 971 | 657 | 801 | 88.44 | x | 0.34 |
| CE9 | 103 | 85 | 81 | 1.33 | x | 0 |
| CE10 | 121 | 96 | 87 | 1.78 | x | 0 |
| CE11 | 101 | 75 | 96 | 1.78 | x | 0 |
| CE12 | 177 | 135 | 174 | 48.89 | x | 0.11 |

As shown in Table 3 and FIGS. 2-4, Example E1 of the present disclosure has a low surface roughness and high bonding surface area (provided by a plurality of nanoscale pores) on the matte side, with Rz being 150 nm or less, Sa being 100 nm or less, Sq being 100 nm or less, and Sdr being 2% or higher. Similarly, Examples E2-E8 of the present disclosure can also achieve both low surface roughness and high bonding surface area (provided by a plurality of nanoscale pores) on the matte side.

In comparison with Examples E1-E8, Comparative Examples CE1-CE8 have much higher surface roughness and no nanoscale pores on the matte side. This may be due to the lack of bis-(sodium sulfopropyl)-disulfide and/or a nitrogen-containing cationic polymer in the electrolyte solution. However, too high surface roughness may cause poor performance such as signal transmittance, thus limiting further applications.

In comparison with Examples E1-E8, Comparative Examples CE9-CE10 have a lower Sdr and no nanoscale pores on the matte side. This may be due to the lack of chloride ion, bis-(sodium sulfopropyl)-disulfide and a nitrogen-containing cationic polymer in the electrolyte solution.

Comparative Example CE11 is a commercialized electrodeposited copper foil with considerably smooth surface. Its matte side has low surface roughness, with Rz being 150 nm or less, Sa being 100 nm or less, and Sq being 100 nm or less. However, the SEM image shows that it has no nanoscale pores on the matte side, and the AFM data shows that it has a Sdr lower than 2%, which results in poor interfacial bonding strength with substrate and needs further roughing process for practical application.

Comparative Example CE12 is a commercialized electrodeposited copper foil having higher surface roughness, with Rz being higher than 150 nm, Sa being higher than 100 nm, Sq being higher than 100 nm. It has no nanoscale pores on the matte side and has a Sdr larger than 2% as confirmed by SEM image and AFM data while it has poor peeling strength.

While some embodiments are provided in the specification, they are only illustrative of the present disclosure and are not intended to limit the protection scope of the present disclosure. Persons skilled in the art may proceed with a variety of modifications based on the disclosure as described without departing from the principle thereof. The protection scope of the present disclosure is as defined in the following claims.

What is claimed is:

1. An electrodeposited copper foil, which has a matte side having:
a maximum height of profile Rz of 150 nm or less;
an arithmetic mean height Sa of 100 nm or less;
a root mean square height Sq of 100 nm or less; and
a developed interfacial area ratio Sdr of 2% or higher;
wherein the Rz, Sa, Sq and Sdr are measured according to ISO 4287-1997 using an atomic force microscope.

2. The electrodeposited copper foil of claim 1, wherein the electrodeposited copper foil has a thickness ranging from 3 μm to 70 μm.

3. The electrodeposited copper foil of claim 1, which has been subjected to at least one surface treatment on at least one side.

4. The electrodeposited copper foil of claim 3, wherein the at least one surface treatment comprises pickling, thermal resistance treatment, anti-oxidation treatment, silane treatment, or a combination thereof.

5. The electrodeposited copper foil of claim 3, wherein the at least one surface treatment does not comprise roughening.

6. A method for manufacturing the electrodeposited copper foil of claim 1, which comprises:
i) providing an electrolyte solution at a temperature of 35° C. to 70° C. in an electrolytic cell equipped with an anode plate and a cathode drum;
ii) applying an electric current at a current density of 20 A/dm² to 100 A/dm² to the anode plate and the cathode drum in rotating state;
iii) providing a copper foil on the cathode drum in rotating state by electrodeposition; and
iv) separating the copper foil obtained from step iii);
wherein the electrolyte solution comprises:
120 g/L to 450 g/L of copper sulfate;
30 g/L to 140 g/L of sulfuric acid;
5 ppm to 60 ppm of chloride ion;
1 ppm to 39 ppm of bis-(sodium sulfopropyl)-disulfide; and
1 ppm to 39 ppm of a nitrogen-containing cationic polymer.

7. The method of claim 6, wherein a total amount of chloride ion, bis-(sodium sulfopropyl)-disulfide and the nitrogen-containing cationic polymer is 100 ppm or less.

8. The method of claim 6, the nitrogen-containing cationic polymer is a reaction product of a diamine of Formula (I) and a diepoxide of Formula (II) in 1:1 molar ratio: 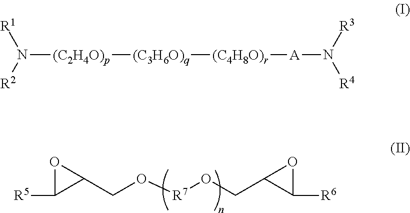
wherein
R¹, R², R³ and R⁴ are independently H or C₁-C₃ alkyl;
R⁵ and R⁶ are independently H or C₁-C₄ alkyl;
R⁷ is a divalent linking group selected from the group consisting of C₂-C₈ alkylene, C₅-C₁₀ cycloalkylene, and C₁-C₄ alkylene-C₅-C₁₀ cycloalkylene-C₁-C₄ alkylene, and R⁷ is optionally substituted with C₁-C₄ alkyl or —OH;
A is a divalent linking group selected from the group consisting of C₂-C₈ alkylene, C₅-C₁₀ cycloalkylene, C₁-C₄ alkylene-C₅-C₁₀ cycloalkylene-C₁-C₄ alkylene, C₆-C₂₀ arylene, and C₁-C₄ alkylene-C₆-C₂₀ arylene-C₁-C₄ alkylene, and A is optionally substituted with C₁-C₄ alkyl or —OH;
p, q and r are independently an integer of 0 to 10, with the proviso that p, q and r are not simultaneously 0;
n is an integer of 1 to 10; and
the nitrogen-containing cationic polymer has a weight average molecular weight of 1,000 or less.

9. An article which comprises the electrodeposited copper foil of claim 1.

10. The article of claim 9 which is an anode electrode collector, a resin-coated copper, a copper clad laminate, a flexible copper clad laminate, a rigid printed circuit board, a flexible printed circuit board, or a rigid-flexible printed circuit board.
